(19) United States
(12) Patent Application Publication
(10) Pub. No.: US 2025/0336464 A1
(43) Pub. Date: Oct. 30, 2025

(54) RADIATION MONITORING USING ACCUMULATED PARITY OF NON-PROTECTED LATCHES

(71) Applicant: Micron Technology, Inc., Boise, ID (US)

(72) Inventors: Kevin G. Werhane, Kuna, ID (US); Jason M. Johnson, Nampa, ID (US); Yoshinori Fujiwara, Boise, ID (US); Daniel S. Miller, Boise, ID (US); Takuya Tamano, Boise, ID (US)

(21) Appl. No.: 19/090,075

(22) Filed: Mar. 25, 2025

Related U.S. Application Data
(60) Provisional application No. 63/640,770, filed on Apr. 30, 2024.

(51) Int. Cl. G11C 29/42; G11C 29/12; G11C 29/48

(52) U.S. Cl. CPC G11C 29/42; G11C 29/1201; G11C 29/48

(57) ABSTRACT

Methods, systems, and devices for radiation monitoring using accumulated parity of non-protected latches are described. An array of non-protected latches store data over time and may be monitored using one or more latches to determine whether one or more errors occur. In some cases, the array may include multiple lanes of latches, where each lane may include a lane latch for parity testing and an output latch. During a parity scan, parity may be periodically generated for the data of each lane and compared to previous parity results to keep track of any soft error events that occur. The parity results for each lane may be combined to output an error flag. In some examples, the error flag may be output to a mode register, and parity testing may be performed based on one or more commands, modes, one or more counters, or with error correction operations.

### CROSS REFERENCE

The present application for Patent claims priority to U.S. Patent Application No. 63/640,770 by Werhane et al., entitled “RADIATION MONITORING USING ACCUMULATED PARITY OF NON-PROTECTED LATCHES,” filed Apr. 30, 2024, which is assigned to the assignee hereof, and which is expressly incorporated by reference in its entirety herein.

### TECHNICAL FIELD

The following relates to one or more systems for memory, including radiation monitoring using accumulated parity of non-protected latches.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports radiation monitoring using accumulated parity of non-protected latches in accordance with examples as disclosed herein.

FIG. 2 shows an example of a circuit diagram that supports radiation monitoring using accumulated parity of non-protected latches in accordance with examples as disclosed herein.

FIG. 3A shows an example of a latch array diagram and FIG. 3B shows an example of a lane latch diagram that support radiation monitoring using accumulated parity of non-protected latches in accordance with examples as disclosed herein.

FIG. 4 shows an example of a lane latch diagram that supports radiation monitoring using accumulated parity of non-protected latches in accordance with examples as disclosed herein.

FIG. 5 shows a block diagram of a memory system that supports radiation monitoring using accumulated parity of non-protected latches in accordance with examples as disclosed herein.

FIG. 6 shows a flowchart illustrating a method or methods that support radiation monitoring using accumulated parity of non-protected latches in accordance with examples as disclosed herein.

### DETAILED DESCRIPTION

Memory systems may be exposed to various different forms of soft errors during a lifetime of system operation. A soft error may be an error caused by a charged particle that strikes one or more elements in the memory system. A soft error may be caused by exposure of the memory system to ionizing radiation, including cosmic radiation particle strikes (e.g., neutron strikes), among other examples. The soft error may in some examples change one or more logic states or may otherwise alter or degrade a reliability of the memory system. In some examples, memory cells may include error correction code (ECC) circuitry to correct bit errors from flipped data states and/or redundant hardening circuitry, such as dual interlocked cell (DICE) circuitry, among other examples, which may be operable to reestablish a flipped state (e.g., two latches that may feedback on each other). However, use of ECC latches and DICE latches (e.g., DICE hardened latches) may hide an effect of particles strikes (or other soft error events) in memory devices, which may result in lost visibility to consequent effects in testing and implementation. Thus, memory system operation and testing may benefit from additional methods for monitoring neutron strikes and other soft error events.

As described herein, an array of non-protected latches (e.g., non-corrected/hardened latches) within a memory system may be used (e.g., repurposed) for radiation monitoring and testing techniques. For example, some memory systems may include non-protected latches that are used for initial testing of various modes of the memory system. As described herein, the latches may be used to store data over relatively long periods of time (e.g., during customer use), and may be monitored over time to determine whether one or more errors occur to the stored data. In some cases, the array of non-protected latches may include multiple lanes of latches connected in series (e.g., daisy-chained). A lane may represent an example of a row, in some examples. Each lane may include an output latch and a lane latch for parity testing in parallel Parity (e.g., parity values, one or more parity bits) may be periodically generated for the data of each lane. Each lane latch may be configured to compare generated parity to previous parity results to keep track of error events that occur within a given time interval. The parity results for each lane may further be combined with each other (e.g., via a series of logical operations) to generate an error indication that indicates whether an error occurred within the array or not. Utilizing lane latches and parity to check for changes to the data may thus enable an external user (e.g., a system administrator or other testing agent) to observe whether a bit flip error occurs during a time period, enabling generation of telemetry data on neutron strike events and characterization (e.g., classification) of different operating environments and device configurations to the risk of soft errors. Other testing (e.g., internal testing) may also use existing devices for characterization as well as further granularity testing (e.g., of individual lanes or processing nodes) to determine susceptibility to soft error events.

In addition to applicability in memory systems as described herein, techniques for radiation monitoring using accumulated parity of non-protected latches may be generally implemented to improve the performance of various electronic devices and systems (including data center applications, cloud computing applications, artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein, including use of the non-protected latches to test for radiation, may provide for improved testing, especially when used across multiple devices. Improved testing may thus provide for improved device design and manufacturing to reduce effects of radiation on future devices, which may improve reliability and performance of future devices and may result in improved device design and support for a variety of different implementations.

In addition to applicability in memory systems described herein, techniques for radiation monitoring using accumulated parity of non-protected latches may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein, including use of the non-protected latches to test for radiation, may provide for improved testing, especially when used across multiple devices, which may improve security and reliability of future devices.

Features of the disclosure are illustrated and described in the context of systems and architectures. Features of the disclosure are further illustrated and described in the context of circuit diagrams, latch array diagrams, lane latch diagrams, block diagrams, and flowcharts.

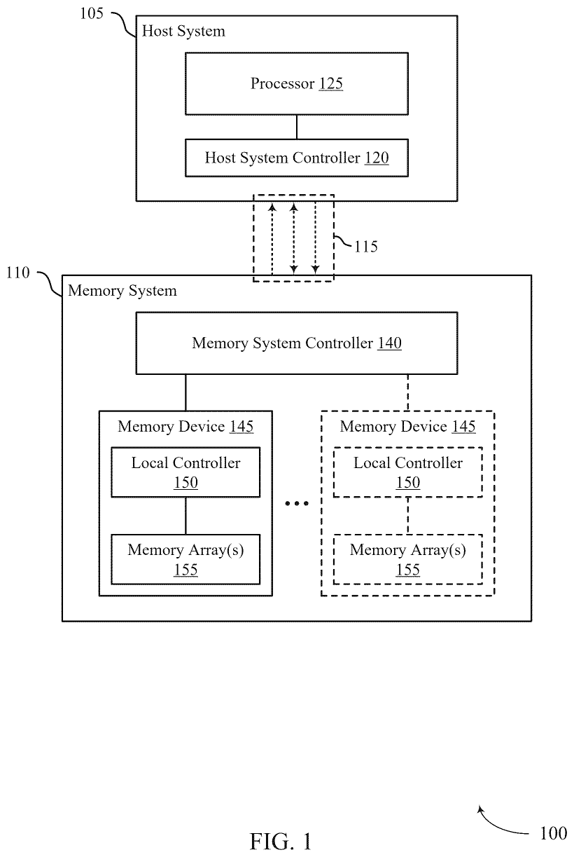

FIG. 1 illustrates an example of a system 100 that supports radiation monitoring using accumulated parity of non-protected latches in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not- or (NOR) memory cells, and not- and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data commands, control information, configuration information, timing information) using one or more channels 115. Each channel 115 may be an example of a transmission medium that carries information, and each channel 115 may include one or more signal paths (e.g, a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, one or more latches and memory circuits of the memory system 110 may be susceptible to flipped data states in memory cells due to different forms of ionizing radiation, including cosmic radiation particle strikes (e.g., neutron strikes). In some examples, memory cells may include ECC circuitry to correct bit errors from flipped data states and/or redundant hardening circuitry such as DICE circuitry, which may be operable to reestablish a flipped state. However, use of ECC latches and DICE latches (e.g., DICE hardened latches) may hide an effect of particles strikes or other soft error events in memory devices, which may result in lost visibility to consequent effects in testing and implementation. Thus, operation and testing of the memory system 110 may benefit from additional methods for monitoring neutron strikes and other soft error events.

As described herein, an array of non-protected latches (e.g., non-corrected/hardened latches) of the memory system 110 may be repurposed to store data over relatively long periods of time (e.g., during customer use), and may be monitored using one or more latches to determine whether one or more errors occur. In some cases, the array (e.g., one or more arrays 155 of multiple memory devices 145) may include multiple lanes of daisy-chained memory cells, where each lane may include an output latch and a lane latch for parity testing in parallel. Parity (e.g., parity values, one or more parity bits) may be periodically generated for the data of each lane and compared to previous parity results to keep track of error events that occur. The parity results for each row may further be combined to output an error flag. Utilizing lane latches and parity to check for changes to the data may thus enable an external user to observe whether a bit flip error occurs during a time period.

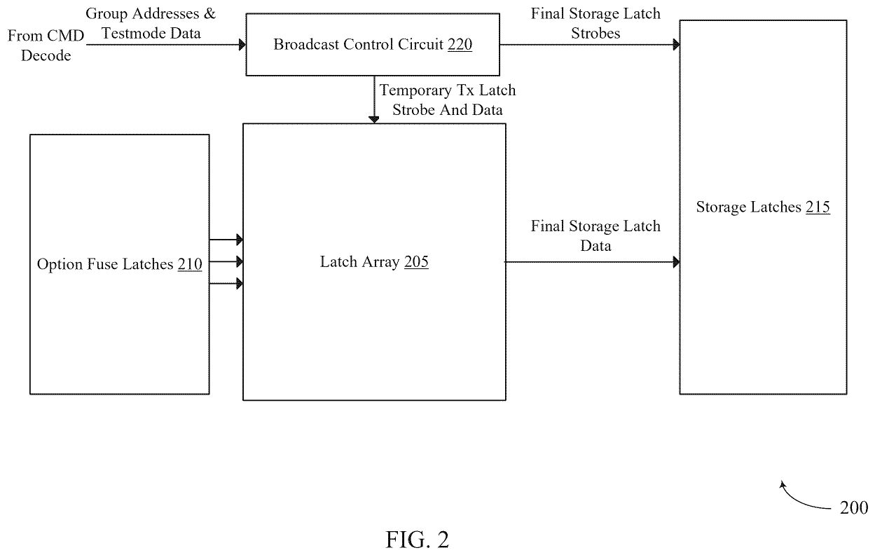

FIG. 2 shows an example of a circuit diagram 200 that supports radiation monitoring using accumulated parity of non-protected latches in accordance with examples as disclosed herein. One or more aspects of the circuit diagram 200 may be implemented by one or more aspects of the system 100. For example, the circuit diagram 200 may illustrate circuitry or other components that may be included on or otherwise associated with one or more memory devices 145 or other components of the memory system 110.

A memory system may include latches and other memory elements or circuits that may be susceptible to flipped data states or other errors associated with unreliable data storage in memory due to different forms of ionizing radiation. For example, ionizing radiation may include particle strikes (e.g., alpha a particles, beta β particles, neutron particles, or other types of particles) as well as electromagnetic radiation (e.g., X-rays, gamma y radiation, or the like), where latches and memory circuits may be particularly susceptible to flipping data states due to particle strikes or radiation, such as by neutron particles. In some examples, as fabrication processes for fabricating memory devices become more efficient, a potential for particle strikes and radiation to affect memory may increase.

In some examples, alpha particles may be easier to shield compared to other types of ionizing radiation, where a packaging of memory may prevent alpha particle penetration (e.g., paper or plastic may stop alpha particle penetration). However, alpha particles may, in some cases, be generated by packaging material itself, which could affect memory. Beta particles may penetrate paper or packaging, but may be stopped by relatively thin plates of material (made of wood, aluminum, etc.), while X-rays and gamma radiation may penetrate paper and thin plates, but may be stopped by lead, iron, and other thick metal plates Neutron particles (e.g., naturally from cosmic radiation, or other artificial sources) may have a deeper penetration than alpha particles and other ionizing radiation. For example, concrete or water (e.g., with a high hydrogen content) may be used to shield for neutron particles. Thus, neutron particles may be able to penetrate stacked die packages (e.g., made of combinations of packaging, thin and/or thick metal plates and silicon) and even some shielded environments.

Ionizing radiation may include enough energy to flip a state of one or more bits in memory (e.g., in DRAM, other memory). Thus, monitoring of fails (e.g., errors in memory) may help a memory system administrator or controller determine if environmental changes may be made to reduce data flips caused by particle strikes. In some cases, a relatively large quantity non-DICE latches, a relatively high radiation rate, or a relatively long sample time may be used to have visibility of such errors, as the effects of ionizing radiation may have a relatively low chance of occurrence in devices. In some examples, DICE latches (e.g., DICE hardened latches) may be used in locations where data is stored for relatively long periods of time, as DICE latches may resist flipping due to a particle strike through reinforced feedback Additionally, or alternatively. ECC (e.g., circuitry and/or processes using redundant data to correct for one or more errors) may be used for one or more memory arrays to correct single bit fails due to low-occurrence particle strikes. However, there may be a relatively large quantity of other latches on a memory die that are not DICE hardened, and thus it may be possible that multiple particle strikes could cause uncorrectable errors in one or more memory arrays. Thus, it may be beneficial to continue to monitor particle strike rates to calculate the risk of these errors, for example, even when using DICE hardening and ECC in memory.

With memory correction methods, such as for ECC latches (e.g., latches protected by ECC), and DICE latches (e.g., DICE hardened latches), different computing architectures (e.g., large-scale commercial server farms, smaller scale server farms) may not be able to monitor radiation effectively. For example, as many ionizing particle strikes may be corrected by ECC or DICE latches, it may be difficult to measure a quantity of strikes that occur in real world situations. In a lab environment (e.g., using high intensity beams), non-corrected/hardened latches may be used to measure how ionizing radiation would affect circuits in testing. However, ECC and DICE latches may hide the effect of particle strikes and prevent or obscure results in testing, while testing in such an environment may not be indicative of data-center radiation conditions. Server and data-center environments may further include an increased chance of particle strikes and effects in systems due to increased data concentration (e.g., increased quantity of dies or bit density). However, although such environments may present an opportunity to gather data (e.g., data center telemetry), ECC and DICE latches may prevent visibility. Thus, memory system operation and testing may benefit from additional methods for monitoring neutron strikes and other soft error events.

Techniques described herein provide for leveraging one or more non-protected latches that are present within a memory system to support improved radiation monitoring. For example, some memory systems may include non-protected latches for use in one or more applications, including circuitry for testmode latching and broadcasting. A non-protected latch may be a latch or other component operable to store data that does not include any feedback circuitry, ECC, or other error correcting capabilities. In the example of FIG. 2, the circuit diagram 200 may include a latch array 205, which may be an array of non-protected latches (e.g., non-DICE latches) as part of a testmode latching and broadcasting circuit within a memory system. The non-protected latches may, in some cases, be referred to as “master” or “daisy-chain” testmode latches and may hold data (e.g., fuse data, local option data) from one or more option fuse latches 210 (e.g., option fuses) before the data is broadcast to a subsequent destination (e.g., as final storage latch data). For example, the data may be broadcast to one or more storage latches 215. In some examples, the option fuse latches 210 and the storage latches 215 may be examples of DICE latches (e.g., local DICE latches). A broadcast control circuit 220 may, in some examples, receive one or more group addresses and testmode data from a command (CMD) decode, and may transmit temporary transmission latch strobe signals and data to the latch array 205 as well as transmit final storage latch strobe signals to the storage latches 215. In some examples, the latches of the latch array 205 may be used during initialization or testmode latching sequences during internal testing may be idle during usage (e.g., by a user, a customer). For example, the latch array 205 may be used to distribute option information across a die at power up of a device, but may otherwise be idle.

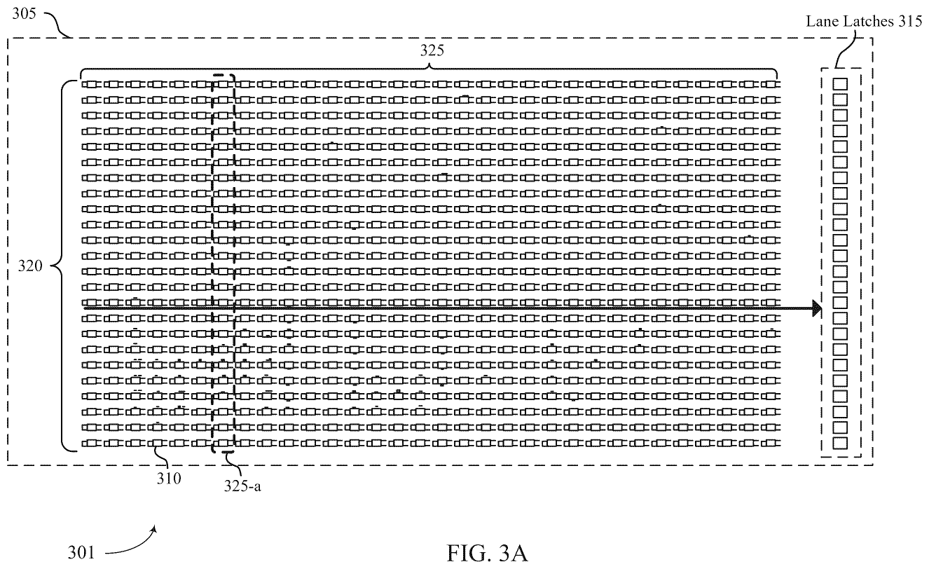

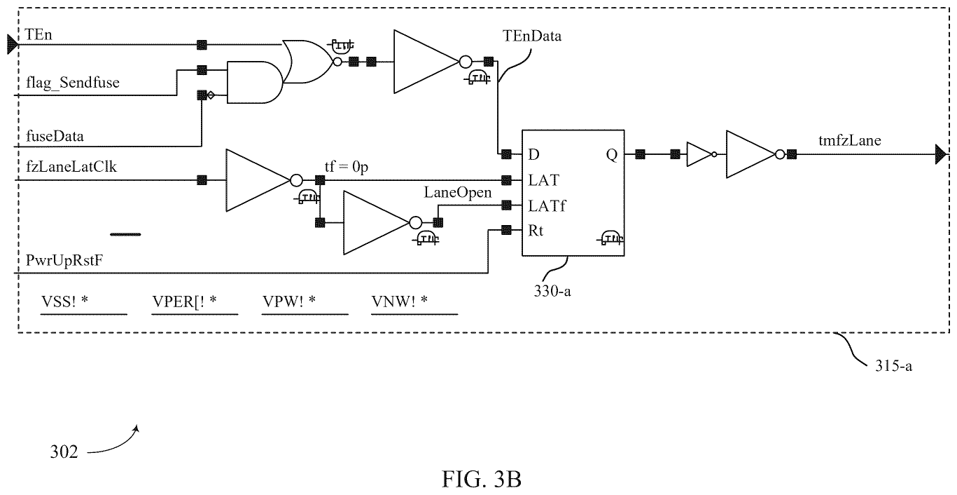

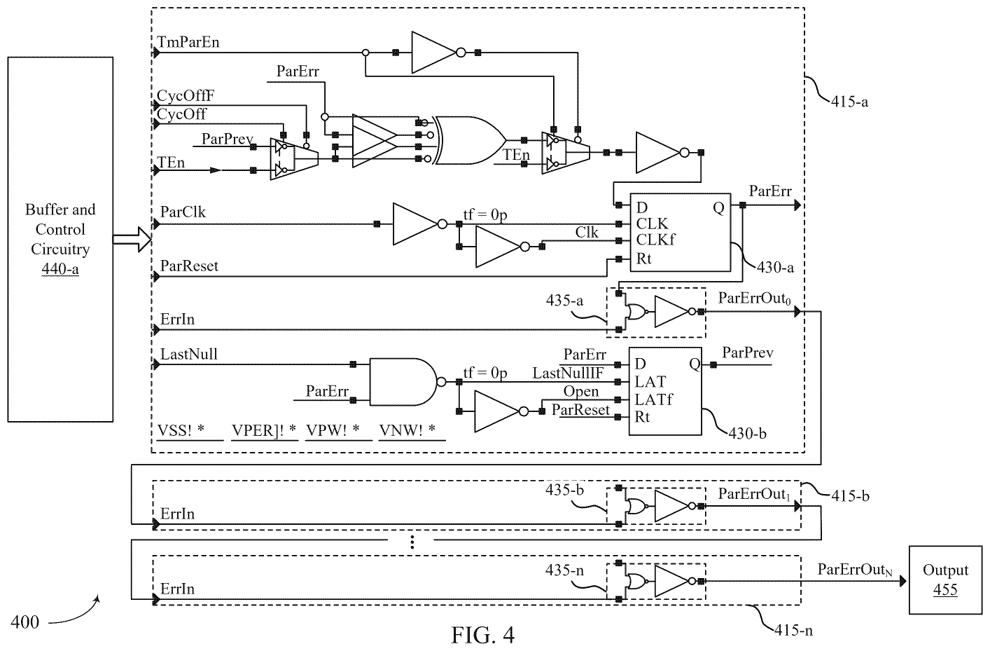

As described herein, a memory system may repurpose one or more of the non-protected latches, such as the latch array 205, for use in neutron strike monitoring. For example, the latch array 205 may be used to store known data for relatively long periods of time, where the non-protected latches (e.g., in a block) may be monitored and checked for changes to the data (e.g., idle during DRAM mission mode). For example, a memory system may periodically check for changes in parity in each lane (e.g., row of latches, set of latches) of the latch array 205. In some examples, the latch array 205 may include a lane latch corresponding to each lane. The lane latch may include circuitry, logic, or both that is configured to accumulate parity for the respective lane and pass the parity to a next lane latch in a series of lane latches. The latch array 205 may, in accordance with the sequence of lane latches, combine the parity results per lane to generate one error indication to indicate whether at least one error occurred in the latch array 205 during a period of time. The configuration of the lane latches are described in further detail elsewhere herein, including with reference to FIGS. 3A, 3B, and 4.

The techniques described herein may thus provide a particle strike monitoring feature within a memory system which may be used individually or in combination with multiple other memory systems (e.g., for use in relatively large or small server farms) to monitor for effects of radiation. For example, although a frequency of the effects of particle strikes and radiation may be small, relatively large concentrations of latch arrays 205 (e.g., within server centers) may produce a volume of data usable to monitor the particle strikes under varying conditions. For example, each memory device of a memory system may include one or more stacked dies each with a latch array 205, and a server farm may include a relatively large quantity of memory systems. Thus, a relatively large amount of latches may be monitored over time within a server farm or other multi-device environment, which may provide data that could be used to compare packaging materials, location, altitude, shielding, orientation, among other factors in a server farm, data center, cloud-based service, or other memory system environment. In some cases, such testing may provide benefits for both high-bit consumption (e.g., data center) users and critical-bit utility (e.g., functional safety (FuSa)) users.

FIG. 3A shows an example of a latch array diagram 301 and FIG. 3B shows an example of a lane latch diagram 302 that support radiation monitoring using accumulated parity of non-protected latches in accordance with examples as disclosed herein. One or more aspects of the latch array diagram 301 and the lane latch diagram 302 may be implemented by one or more aspects of the system 100 and the circuit diagram 200 as described with reference to FIGS. 1 and 2. For example, the latch array diagram 301 may represent a latch array 305, which may be an example of the latch array 205 and may include one or more non-protected latches 310. The latch array 305 may, in some cases, represent circuitry of one or more memory devices 145 (e.g., of one or more dies or packages) of a memory system 110. The lane latch diagram 302 may further illustrate a structure for a lane latch 315 of the latch array 305.

In the example of FIG. 3A, the latch array diagram 301 may include one or more lanes 320 (e.g., one or more testmode lanes, rows, sets, sections) of non-protected latches 310 (or other sections of a memory device 145). A lane 320 may represent an example of a portion of the array, a row of the array, a set of one or more latches, or any combination thereof. Each lane 320 may be a testmode lane, where a quantity N of the lanes 320 may correspond to a data bus width. In some examples, each lane 320 may include a serial, daisy-chain style of connected non-protected latches 310 in which an output of each non-protected latch 310 (e.g., memory cell) may be coupled with an input of a next non-protected latch 310 of a same respective lane 320. Additionally, or alternatively, the non-protected latches 310 may be coupled in any configuration within a given lane (e.g., in parallel or some other configuration).

Each column of non-protected latches 310 may represent a phase 325, which may correspond to a phase of a broadcast at which data from the non-protected latches 310 from each lane 320 would be output. For example, a phase 325-a may correspond to a phase X of a quantity M of phases 325 for each of the N lanes 320 (e.g., of 32 total phases for 24 lanes as illustrated). In some examples, the non-protected latches 310 may be part of a single array (e.g., as illustrated), or may be split into multiple arrays (e.g., into four quadrants/cycles each with a subset of the M phases 325 with N lanes 320 and an OR operation combining outputs). In some examples, alternating data termination may be used to send lane-check data during Null-Phase for FuSa enabled designs. The latch array 305 may also include one or more lane latches 315 for broadcasting data from the non-protected latches 310. For example, the latch array 305 may include a lane latch 315 coupled with an output of each respective lane 320 of the N lanes (e.g., coupled with a last lane latch 315 of a respective lane 320).

In the example of FIG. 3B, a lane latch 315-a (e.g., an existing lane latch representing any of the lane latches 315 with one per testmode lane) may include one or more of logic and latch circuitry for use with an output of data from a respective lane 320. The lane latch 315-a may be an example of a wrapper or interface through which data of the respective Jane 320 may pass before being sent to local final storage. For example, the lane latch 315-a may include an input TEn that may represent data output by non-protected latches 310 of a respective lane 320. The lane latch 315-a may also include a flip-flop 330-a, which may include inputs D, LAT, LATf, and Rr. In some cases, a signal TEnData input into D may result from performing a not OR (NOR) operation and a NOT operation on the signal TEn and on a result of a logical AND operation of signals flag Sendfuse (e.g., enabling sending fuse data) and fuseData (e.g., data from option fuses). The inputs LAT and LATf may further include a single NOT operation and a double NOT operation on a lane clock signal fzLaneLatClk, respectively, while the input Rt may receive a signal PwrUpRsIF (e.g., power up signal). In some examples, the flip-flop 330-a may include an output Q which may result in a final output signal tmfzLane after performing a double NOT operation on the output Q. The signals, inputs, outputs, and logical operations of the lane latch 315-a may, in some cases, involve different voltages (e.g., VSS. VPER, VPW, and VNW).

During a broadcast operation, the data of each lane 320 may output to a respective lane latch 315 according to a fzLaneLatClk clock signal (e.g., on each rising edge or each falling edge). For example, of each of the M phases, data within a respective non-protected latch 310 of a current phase may be output for each of the N lanes to a respective lane latch 315 as TEn along with fusedata (e.g., EfuseData), where each respective phase may be output according to a imStrobePh value. This may be performed on power up to transfer the fuse data that is temporarily stored in the latch array 305 (e.g, EfuseData<*>) to the final storage (e.g., local DICE latches). In some cases, EfuseData<*> and TEn<*> may represent vectors corresponding to the M phases. Otherwise, the signals and circuit described may be unused for fuse data during operation after initial power up or when not in a test mode. Although the lane latch 315-a may be shown including the illustrated logical operations, a lane latch 315-a may include any combination of logical operations and circuitry to enable testmode latching and broadcast, among other operations.

As described herein, the latch array 305 (when not in use), may store data to monitor (e.g., account for, track) and detect one or more neutron strikes. For example, a new lane latch may be added to each respective lane 320, or the lane latches 315 may otherwise be modified to accumulate a parity result (e.g., parity information, parity value) for all the bits (phases) in a respective lane 320 (e.g., 32 bits corresponding to the 32 phases). The parity result may be stored within the lane latch until a next parity scan is run at a next time, and may be compared with the next parity result to determine any differences, as described in further detail elsewhere herein, including with reference to FIG. 4. The memory system 110 may then combine (e.g., via an OR operation) the results for each of the lanes 320 to determine if any errors were present in the latch array 305. In some examples, the new latch may be added in parallel with a corresponding lane latch 315 (e.g., for using both latches at the same time) or may be coupled with a selection component (e.g., TmParEn multiplexer (MUX)) to which the respective lane latch 315 is coupled. For example, the selection component may select one or the other of the lane latches based on a type of test operation or mode of the memory system 110 (e.g., for normal broadcast mode or for a parity scan mode). Additionally, or alternatively, the new lane latch may replace the corresponding lane latch 315, or the lane latch 315 may be updated to include the new circuit in addition to or alternate to the previous circuitry to support broadcast, parity information tracking, or both.

FIG. 4 shows an example of a lane latch diagram 400 that supports radiation monitoring using accumulated parity of non-protected latches in accordance with examples as disclosed herein. One or more aspects of the lane latch diagram 400 may be implemented by one or more aspects of the system 100, the circuit diagram 200, the latch array diagram 301, and the lane latch diagram 302 as described with reference to FIGS. 1, 2, 3A, and 3B. For example, the lane latch diagram 400 may illustrate a structure with logic circuitry for a lane latch 415, such as a lane latch 415-a, that may be added in addition to or instead of one or more lane latches 315 as described with reference to FIGS. 3A and 3B.

As described herein, the memory system 110 (e.g., within each memory device 145) may include a set of multiple (e.g., an array of) option fuse latches (e.g., option fuse latches 210) and a set of multiple non-protected latches (e.g., the latch array 305 of non-protected latches 310), one or more of which may be coupled with one or more of the option fuse latches. The set of multiple non-protected latches may be referred to as an array of non-protected latches and may include a set of multiple lanes (e.g., lanes 320, sections, sets, rows) and may be configured to support one or more test modes. For example, the memory system 110 may also include a set of multiple lane latches 415, including a respective lane latch 415 coupled with an output of each respective lane and logic circuitry coupled with the lane latches 415 and configured to generate an error indication by combining parity information. The memory system 110 may, in some cases, include an array of protected (or non-protected) latches coupled with logic circuitry of one or more lane latches (e.g., of a lane latch 415, or a corresponding parallel lane latch) which may be configured to store data output by corresponding lanes of latches (e.g., one or more final destination DICE latches separate from or part of the radiation sensitive latches).

In some examples, a lane latch 415 may be an example of one of the lane latches 315 as described with reference to FIGS. 3A and 3B. Additionally, or alternatively, the lane latch 415 may be coupled with a respective lane latch 315 (e.g., in a serial configuration). A Lane latch 415, such as the lane latch 415-a illustrated in FIG. 4, may include inputs ParPrev and TEn coupled with an input of a multiplexing circuit, or multiplexer (MUX), that may also be coupled with inputs CycOffF and CycOff. The output of the MUX may be coupled with a first input of an XOR circuit and an amplification circuit (e.g., a buffer, an amplifier) coupled with a second input of the XOR circuit. The lane latch 415-a may also include an input ParErr coupled with an input of a second amplification circuit and a third input of the XOR circuit, where an output of the second amplification circuit may be coupled with a fourth input of the XOR circuit. Further, an input TEn and an output of the XOR circuit may be coupled with a second MUX that is also coupled with an input TmParEn both directly and via an inverter. An output of the second MUX may be coupled with an input of another inverter that may have an output coupled with a first input D of a flip-flop 430-a. The lane latch 415-a may also include an input ParClk coupled with an input of an inverter, which may be coupled with a second input CLK and another inverter coupled with a third input CLKf of the flip-flop 430-a (e.g., latch). The lane latch 415-a may further include an input ParReset coupled with a fourth input of the flip-flop 430-a. An output Q of the flip-flop 430-a may be coupled with an input of a logic circuit (e.g., logic circuitry) 435-a of the memory system 110, where the logic circuit 435-a may include an AND circuit and an inverter in series that may be separate from or part of the lane latch 415-a (e.g., and output of the lane latch 415-a may be Q which may be coupled with the logic circuit 435-a). An input ErrIn may also be coupled with a second input of the logic circuit 435-a, where an output of the logic circuit 435-a may be represented by ParErrOut₀.

A second flip-flop 430-b may also be included in the lane latch 415 with inputs D, LAT, LATf, and Rt coupled with inputs ParErr, LastNullF, Open, and ParReset, respectively. In some cases, the inputs LastNullF and Open may be examples of an output of an AND circuit with LastNull and ParERR as inputs, and an inverter of the output of the AND circuit, respectively. Similar to FIG. 3B, the lane latch 415-a and related circuitry may operate according to one or more different voltages (e.g., VSS, VPER, VPW, and VNW).

In some examples, the memory system 110 may include a quantity of similar lane latches 415, including a lane latch 415-a, 415-b, up to a lane latch 415-n for N total lanes within an array of non-protected latches. As illustrated in FIG. 3A, each lane latch 415 may be coupled with an output of a respective lane of non-protected latches, which may be a row of latches, a set of latches, a portion of an array, or some other set of latches coupled in a serial configuration. Each lane latch 415 may additionally, or alternatively, be coupled with another lane latch 315 associated with the respective lane. Each lane latch 415 may be coupled with another lane latch 415 for a next or subsequent lane in the array of non-protected latches via logic circuits 435. The logic circuits 435 may be included in or otherwise coupled with the lane latches 415. For example, output ParErrOut₀ of the lane latch 415-a may couple with an input ErrIn for a next lane latch 415-b (e.g., a next lane latch 415-b below the lane latch 415-a in a column). ErrIn of the lane latch 415-b may couple with an input of logic circuit 435-b, which may also be coupled with an output Q of a flip-flop 430 generated for the lane latch 415-b and corresponding lane. An output parity value of the logic circuit 435-b. ParErrOut₁, may be coupled as ErrIn for a next lane latch 415-b with a similar configuration. The combination of parity values across consecutive lanes may continue across lane latches 415, up to a lane latch 415-n and a logic circuit 435-n, where a final output (e.g., an error indication) may be ParErrOut_{N}. In such an example, the lane latches 415 may be coupled in a serial configuration. Additionally, or alternatively, each lane latch 415 may be independent of each other. In some examples, the circuitry illustrated in FIG. 4 may support monitoring bit flips by checking accumulated parity, where the lane latch 415-a may be able to periodically scan latch chains and store or report fail rates (e.g., when not broadcasting or loading testmodes).

The lane latches 415 may perform one or more passes (e.g., scans) over time, such as periodically or at some other frequency or time intervals. During each pass (e.g., parity scan), the memory system 110 may act as a parity accumulator (e.g., via one or more lane latches 415) and may generate parity bits. For example, the memory system 110 may store, at a first time, first data in a first lane (e.g., section, row) of the set of multiple non-protected latches (e.g., an array). The memory system 110 may generate a first parity value (e.g., ParErr for a first pass) based on (e.g., associated with, in accordance with) the initially stored data. In some cases, generating the first parity value may be based on accumulating parity using the XOR function of the data (e.g., to count a quantity of 1's or 0's as even or odd). The first parity value may include one or more bits that represent the parity for the first data in the first lane. The memory system 110 may store the first parity value in the lane latch 415-a associated with the first lane, for example, in the flip-flop 430-b (e.g., may store ParErr as ParPrev for a next pass). At a second time that is after the first time, the memory system 110 may generate a second parity value (e.g., ParErr for a second pass) associated with second data stored in the lane at the second time. The second data may be based on the first data and one or more environmental conditions (e.g., ionizing radiation changing the first data) to which the first lane is exposed between the first time and the second time. For example, the second data may be the same as the first data or may represent one or more changes (e.g., errors) in the first data due to radiation or other environmental conditions to which the memory system was exposed between the first time and the second time.

For each pass, a generated parity value may be compared to a previous parity value of the lane latch 415-a. For example, the generated second parity value may be compared to the first parity value to generate a third parity value (e.g., parity information) on the final clock ParClk (e.g., aligned on a clock for transmission to external latches). The memory system 110 may perform an exclusive- or (XOR) function of ParErr and ParPrev, and may output a new ParErr, or a third parity value, as Q to indicate whether there is any difference between the first and second parity values. In some cases, a difference may indicate that there is at least one error in the corresponding first section (e.g., corresponding Jane 320). After outputting the result of the comparison, ParErr, may be stored as ParPrev in the flip-flop 430-b (e.g., latch) for a third pass. The memory system 110 may perform similar procedures for each section (e.g., lane 320) of the set of multiple non-protected latches using a corresponding lane latch 415. For example, the memory system 110 may generate a fourth parity value ParErr associated with a second lane (or section) among additional parity information ParErr for further sections using lane latches 415-b through 415-n with corresponding logic operations. In some examples, by comparing ParErr to ParPrev, an error indication may be latched until a reset command or other operation clears it. For example, once an error is detected, a stored ParPrev may result in an indication of an error regardless of errors detected afterwards. Additionally, or alternatively, monitoring may be frozen (e.g., paused, stopped) after detecting an error.

In some examples, the memory system 110 may perform any quantity of passes over time. For example, the memory system 110 may store, after generating the third parity value ParErr, the second parity value in the lane latch 415-a (e.g., to the flip-flop 430-b as ParPrev), and may generate a fourth parity value associated with third data stored in the first section at a third time (e.g., for a third pass) where the third data be based on (e.g., altered) the second data and the one or more environmental conditions to which the first section of the array is exposed between the second time and the third time. The memory system 110 may then compare the third parity value and the fourth parity value and generate a fifth parity value (e.g., additional parity information, a ParErr comparison result output as Q) associated with the first lane based on the comparing. In some cases, the first time, the second time, and the third time may be based on the clock signal ParClk of the memory system. Further, multiple indications of errors (e.g., indications of whether an error occurred or not during multiple instances) may be output for multiple time periods.

In some examples, as illustrated in FIG. 4, the output parity values ParErr may be combined to output a single error indication (e.g., may be daisy chain OR connected). For example, the memory system 110 may combine, in accordance with one or more logical operations (e.g., in accordance with logical OR operations), the parity value ParErrOut₀ (e.g., which may be the same as ParErr for the lane latch 415-a) and the parity value ParErrOut₁ using the logic circuit 435-b, and may continue to combine parity values for up to N lanes and lane latches 415, where ParErrOut_{N} (e.g., an error indication, flag) may be based on the combining. Thus, a daisy chain OR of all parity values may be high when any of the lanes (e.g., and corresponding latch chains) have a difference in parity from a prior scan. In some examples, the resulting error indication. ParErrOut_{N}, may be output to an output 455, which may be any of an interface (e.g., pin for reading), a mod register, or the like. For example, a combined parity value ParErrOut_{N}, may be output (e.g., stored to) as ParErrOutMR to a mode register of the memory system 110 configured to store the indication and operable to be read by an external system (e.g., the host system 105 or another external system), and may be an example of an external mode register to be read (MRR) by a system or test. Additionally, or alternatively, the memory system 110 may output a set of multiple error indications ParErrOut associated with a set of multiple time periods of operation of the memory system 110. Each error indication ParErrOut may indicate whether a respective error occurred within the array of non-protected latches during a respective time period. In some examples, generation of each error indication (e.g., accumulation pass and parity bit and parity information generation) may be based on (e.g., initiated by) a register command (e.g., MR load/clear), a testmode, a parity scan mode, one or more counters of the memory system (e.g., internal counting mechanism CBR rollovers etc.), may be performed with error correction operation (e.g., ECS), or any combination thereof. Further, such output may be automated during broadcast, or may have a manual input for the data or to perform such comparisons during testing.

Additionally, or alternatively, the memory system 110 may output parity values resulting from comparisons within each individual lane latch 415, or ParErr (e.g., without combining with other lane parity information). For example, the parity value ParErr output as Q for a respective pass (e g . . . broadcast cycle) may be output by an individual lane latch 415 to circuitry for storing or indicating errors (e.g., for analysis or testing), which may provide a greater granularity as compared with outputting the final error indication as it may support observation or storage of error indications per section (e.g., per lane 320 as ParErr may indicate whether an error occurred within the lane). That is, a system administrator may utilize the per-lane parity information, if output, to identify a specific location of errors within the array of non-protected latches. Further, the memory system 110 may, in some cases, be configured so that parity values (e.g., parity bits) for a pass and a respective lane latch 415 and corresponding section of the array (e.g., lane, row, set), may be output directly or stored to a location for observation (e.g., as a vector of parity values or parity bits). Additionally, or alternatively, there may be a dedicated latch for each non-protected latch of the array to allow determining where (e.g., in what phase and in what latch) an error occurred within a lane. Additionally, or alternatively, a logic OR may be removed so that XOR parity values may be accumulated for all of the lane latches 415, and may be compared with a previous pass for all lane latches.

In some examples, one or more inputs of the lane latch 415-a may be coupled with buffer and control circuitry 440-a of the memory system 110. For example, the buffer and control circuitry 440-a may include one or more logic circuits (e.g., amplification circuits, AND circuits, OR circuits, NAND circuits, not- or (NOR) circuits. XOR circuits, inverters, and the like) and may buffer signals for the any of the inputs of the lane latch 415-a (e.g., the inputs CycOff, ParClk, LastNull). In some cases, the buffer and control circuitry 440-a may be available locally to a testmode broadcast area where there may be buffer and control curtails once per testmode broadcast block (e.g., about 2 per die). In some examples, the operations described herein may be performed according to automatic broadcast (e.g., BroadcastTMterm) with fzLaneLatClk, CycOff, and TmParEn<1> using ParClk. Otherwise, parity scans may be performed by receiving manual command signals, data signals, and/or a manual clock signal (e.g., in place of ParClk).

The described techniques may thereby provide for circuitry that is configured to generate a parity value for a lane of non-protected latches, compare parity values for a given lane across periodic passes, and then combine parity values for the multiple lanes within an array of non-protected latches to generate a resulting error indication for the memory array. The circuitry may include one or more lane latches 415, which may be coupled with or otherwise included in the lane latches 315 as described with reference to FIGS. 3A and 3B. By generating the parity information per lane, the resulting error indication for the array, or both, the memory system may monitor for soft errors that occur within the latch array over time due to environmental factors, such as ionizing radiation, among other examples. The memory system may be combined with one or more other memory systems (e.g., in a server farm or some other test environment), and the error indications per system may be combined to obtain a relatively large set of test data that represents effects of radiation to memory storage elements over time. In some examples, the array of non-protected latches may operate in a test mode to support the storage of known data and the parity information monitoring. The array of non-protected latches may additionally, or alternatively, support one or more other test modes (e.g., during initialization of the memory system) for broadcast and control testing, as described with reference to FIG. 2. The test modes may be enabled or disabled dynamically based on an input to the system or one or more parameters, or any combination thereof.

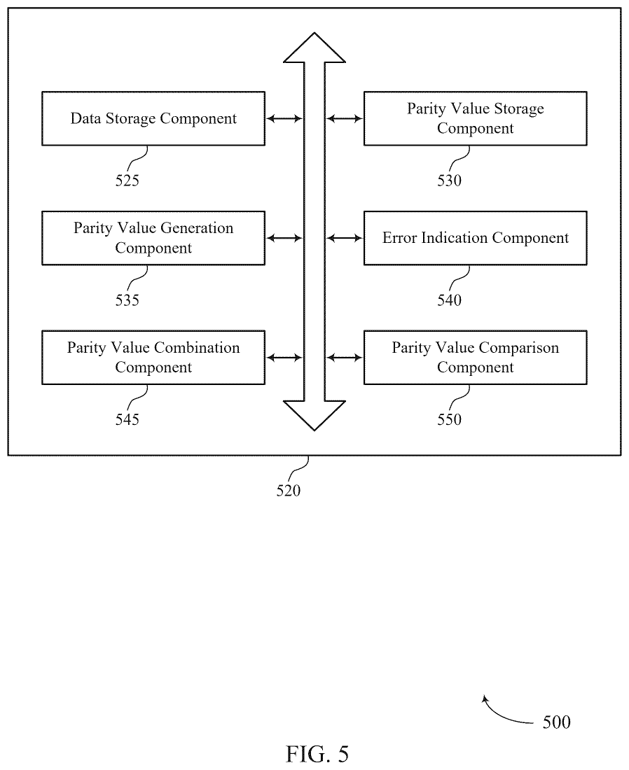

FIG. 5 shows a block diagram 500 of a memory system 520 that supports radiation monitoring using accumulated parity of non-protected latches in accordance with examples as disclosed herein. The memory system 520 may be an example of aspects of a memory system as described with reference to FIGS. 1 through 4. The memory system 520, or various components thereof, may be an example of means for performing various aspects of radiation monitoring using accumulated parity of non-protected latches as described herein. For example, the memory system 520 may include a data storage component 525, a parity value storage component 530, a parity value generation component 535, an error indication component 540, a parity value combination component 545, a parity value comparison component 550, or any combination thereof. Each of these components, or components of subcomponents thereof (e.g., one or more processors, one or more memories), may communicate, directly or indirectly, with one another (e.g., via one or more buses).

The data storage component 525 may be configured as or otherwise support a means for storing, at a first time, first data in a first section of an array of non-protected latches of the memory system. The parity value storage component 530 may be configured as or otherwise support a means for storing, in a first latch of the memory system, a first parity value associated with the first data stored in the first section of the array, the first latch associated with the first section of the array. The parity value generation component 535 may be configured as or otherwise support a means for generating, at a second time, a second parity value associated with second data that is stored in the first section of the array of non-protected latches at the second time, where the second data is based at least in part on the first data and one or more environmental conditions to which the first section of the array is exposed between the first time and the second time. In some examples, the parity value generation component 535 may be configured as or otherwise support a means for generating a third parity value associated with the first section of the array based at least in part on the first parity value and the second parity value. The error indication component 540 may be configured as or otherwise support a means for outputting an error indication that indicates whether an error occurred within the array of non-protected latches between the first time and the second time based at least in part on the third parity value associated with the first section of the array.

In some examples, the parity value generation component 535 may be configured as or otherwise support a means for generating a fourth parity value associated with a second section of the array. In some examples, the parity value combination component 545 may be configured as or otherwise support a means for combining, in accordance with one or more logical operations, the third parity value and the fourth parity value, where the error indication is based at least in part on the combining.

In some examples, to support combining the third parity value and the fourth parity value in accordance with the one or more logical operations, the parity value combination component 545 may be configured as or otherwise support a means for combining the third parity value and the fourth parity value in accordance with a logical OR operation, where the first section of the array includes a first set of non-protected latches coupled in a serial configuration and the second section of the array includes a second set of non-protected latches coupled in a serial configuration, and where the first latch associated with the first section of the array is coupled with a second latch associated with the second section of the array in a serial configuration.

In some examples, the parity value comparison component 550 may be configured as or otherwise support a means for comparing the first parity value with the second parity value, where generating the third parity value is based at least in part on the comparing.

In some examples, the parity value storage component 530 may be configured as or otherwise support a means for storing, after generating the third parity value, the third parity value in the first latch. In some examples, the parity value generation component 535 may be configured as or otherwise support a means for generating a fourth parity value associated with third data that is stored in the first section of the array of non-protected latches at a third time, where the third data is based at least in part on the second data and the one or more environmental conditions to which the first section of the array is exposed between the second time and the third time. In some examples, the parity value comparison component 550 may be configured as or otherwise support a means for comparing the third parity value and the fourth parity value. In some examples, the parity value generation component 535 may be configured as or otherwise support a means for generating a fifth parity value associated with the first section of the array based at least in part on the comparing.

In some examples, the first time, the second time, and the third time are based at least in part on a clock signal of the memory system.

In some examples, the parity value generation component 535 may be configured as or otherwise support a means for outputting the third parity value, where the third parity value indicates whether a second error occurred within the first section of the array between the first time and the second time.

In some examples, to support outputting the error indication, the error indication component 540 may be configured as or otherwise support a means for storing the error indication to a register of the memory system, where the register is operable to be read by an external system.

In some examples, the error indication component 540 may be configured as or otherwise support a means for outputting a plurality of error indications associated with a plurality of time periods of operation of the memory system, where each error indication indicates whether a respective error occurred within the array of non-protected latches during a respective time period, and where generation of each error indication of the plurality of error indications is based at least in part on a register command, a test mode, an error correction operation, one or more counters of the memory system, or any combination thereof.

In some examples, the error indication indicates whether the array of non-protected latches was exposed to radiation that may cause the error within the array of non-protected latches between the first time and the second time. In some examples, the one or more environmental conditions include the radiation.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

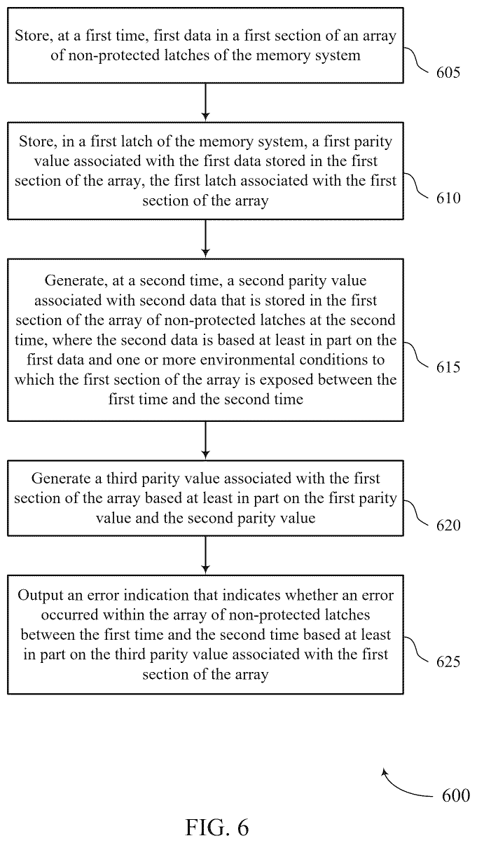

FIG. 6 shows a flowchart illustrating a method 600 that supports radiation monitoring using accumulated parity of non-protected latches in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include storing, at a first time, first data in a first section of an array of non-protected latches of the memory system. In some examples, aspects of the operations of 605 may be performed by a data storage component 525 as described with reference to FIG. 5.

At 610, the method may include storing, in a first latch of the memory system, a first parity value associated with the first data stored in the first section of the array, the first latch associated with the first section of the array. In some examples, aspects of the operations of 610 may be performed by a parity value storage component 530 as described with reference to FIG. 5.

At 615, the method may include generating, at a second time, a second parity value associated with second data that is stored in the first section of the array of non-protected latches at the second time, where the second data is based at least in part on the first data and one or more environmental conditions to which the first section of the array is exposed between the first time and the second time. In some examples, aspects of the operations of 615 may be performed by a parity value generation component 535 as described with reference to FIG. 5.

At 620, the method may include generating a third parity value associated with the first section of the array based at least in part on the first parity value and the second parity value. In some examples, aspects of the operations of 620 may be performed by a parity value generation component 535 as described with reference to FIG. 5.

At 625, the method may include outputting an error indication that indicates whether an error occurred within the array of non-protected latches between the first time and the second time based at least in part on the third parity value associated with the first section of the array. In some examples, aspects of the operations of 625 may be performed by an error indication component 540 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for storing, at a first time, first data in a first section of an array of non-protected latches of the memory system; storing, in a first latch of the memory system, a first parity value associated with the first data stored in the first section of the array, the first latch associated with the first section of the array; generating, at a second time, a second parity value associated with second data that is stored in the first section of the array of non-protected latches at the second time, where the second data is based at least in part on the first data and one or more environmental conditions to which the first section of the array is exposed between the first time and the second time: generating a third parity value associated with the first section of the array based at least in part on the first parity value and the second parity value; and outputting an error indication that indicates whether an error occurred within the array of non-protected latches between the first time and the second time based at least in part on the third parity value associated with the first section of the array.

Aspect 2: The method, apparatus, or non-transitory computer-readable medium of aspect 1, further including operations, features, circuitry, logic, means, or instructions, or any combination thereof for generating a fourth parity value associated with a second section of the array and combining, in accordance with one or more logical operations, the third parity value and the fourth parity value, where the error indication is based at least in part on the combining.

Aspect 3: The method, apparatus, or non-transitory computer-readable medium of aspect 2, where combining the third parity value and the fourth parity value in accordance with the one or more logical operations includes operations, features, circuitry, logic, means, or instructions, or any combination thereof for combining the third parity value and the fourth parity value in accordance with a logical OR operation, where the first section of the array includes a first set of non-protected latches coupled in a serial configuration and the second section of the array includes a second set of non-protected latches coupled in a serial configuration, and where the first latch associated with the first section of the array is coupled with a second latch associated with the second section of the array in a serial configuration.

Aspect 4: The method, apparatus, or non-transitory computer-readable medium of any of aspects 1 through 3, further including operations, features, circuitry, logic, means, or instructions, or any combination thereof for comparing the first parity value with the second parity value, where generating the third parity value is based at least in part on the comparing.

Aspect 5: The method, apparatus, or non-transitory computer-readable medium of any of aspects 1 through 4, further including operations, features, circuitry, logic, means, or instructions, or any combination thereof for storing, after generating the third parity value, the third parity value in the first latch: generating a fourth parity value associated with third data that is stored in the first section of the array of non-protected latches at a third time, where the third data is based at least in part on the second data and the one or more environmental conditions to which the first section of the array is exposed between the second time and the third time: comparing the third parity value and the fourth parity value; and generating a fifth parity value associated with the first section of the array based at least in part on the comparing.

Aspect 6: The method, apparatus, or non-transitory computer-readable medium of aspect 5, where the first time, the second time, and the third time are based at least in part on a clock signal of the memory system.

Aspect 7: The method, apparatus, or non-transitory computer-readable medium of any of aspects 1 through 6, further including operations, features, circuitry, logic, means, or instructions, or any combination thereof for outputting the third parity value, where the third parity value indicates whether a second error occurred within the first section of the array between the first time and the second time.

Aspect 8: The method, apparatus, or non-transitory computer-readable medium of any of aspects 1 through 7, where outputting the error indication includes operations, features, circuitry, logic, means, or instructions, or any combination thereof for storing the error indication to a register of the memory system, where the register is operable to be read by an external system.

Aspect 9: The method, apparatus, or non-transitory computer-readable medium of any of aspects 1 through 8, further including operations, features, circuitry, logic, means, or instructions, or any combination thereof for outputting a plurality of error indications associated with a plurality of time periods of operation of the memory system, where each error indication indicates whether a respective error occurred within the array of non-protected latches during a respective time period, and where generation of each error indication of the plurality of error indications is based at least in part on a register command, a test mode, an error correction operation, one or more counters of the memory system, or any combination thereof.

Aspect 10: The method, apparatus, or non-transitory computer-readable medium of any of aspects 1 through 9, where the error indication indicates whether the array of non-protected latches was exposed to radiation that may cause the error within the array of non-protected latches between the first time and the second time and the one or more environmental conditions include the radiation.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 11: A memory system, including: a plurality of option fuse latches: a plurality of non-protected latches, one or more of which are coupled with one or more of the plurality of option fuse latches, where the plurality of non-protected latches are configured to support one or more test modes for the memory system, and where the plurality of non-protected latches includes a plurality of lanes of non-protected latches; a plurality of lane latches including a respective lane latch coupled with the plurality of lanes of non-protected latches, where the plurality of lane latches includes a respective lane latch coupled with an output of each lane of the plurality of lanes of non-protected latches, and where the respective lane latch for a lane of non-protected latches is configured to generate parity information associated with the lane of non-protected latches; and logic circuitry coupled with the plurality of lane latches and configured to generate an error indication based at least in part on a combination of the parity information generated by the plurality of lane latches.

Aspect 12: The memory system of aspect 11, where each respective lane latch of the plurality of lane latches of the memory system is associated with a corresponding lane of non-protected latches and is configured to generate respective parity information based at least in part on a comparison of a first set of parity bits associated with first data stored in the corresponding lane of non-protected latches at a first time and a second set of parity bits associated with second data stored in the corresponding lane of non-protected latches at a second time.

Aspect 13: The memory system of any of aspects 11 through 12, where the memory system includes: a mode register coupled with the logic circuitry, where the mode register is configured to store the error indication.

Aspect 14: The memory system of any of aspects 11 through 13, where the memory system includes: an array of protected latches coupled with the logic circuitry and configured to store data output by the plurality of non-protected latches.

Aspect 15: The memory system of any of aspects 11 through 14, where each lane of non-protected latches includes a respective plurality of non-protected latches coupled in a serial configuration, an output of each non-protected latch of the respective plurality of non-protected latches in each lane is coupled with an input of a next non-protected latch of the respective plurality of non-protected latches in each lane in accordance with the serial configuration.

Aspect 16: The memory system of any of aspects 11 through 15, where the plurality of lane latches are coupled in a serial configuration, an output of a lane latch of the plurality of lane latches is coupled with an input of a next lane latch of the plurality of lane latches in accordance with the serial configuration.

Aspect 17: The memory system of any of aspects 11 through 16, where the memory system further includes: a plurality of second lane latches, where each second lane latch of the plurality of second lane latches is coupled with an output of a respective lane of the plurality of lanes of non-protected latches, and where each second lane latch is configured to latch data stored in the respective lane of non-protected latches.

Aspect 18: The memory system of aspect 17, where each second lane latch is in a parallel circuit configuration with a respective lane latch of the plurality of lane latches or is coupled with a selection component coupled with the respective lane latch.

Aspect 19: The memory system of any of aspects 11 through 18, where the memory system further includes, buffer circuitry and control circuitry coupled with an input of the plurality of lane latches.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal, however, the signal may represent a bus of signals, where the bus may have a variety of bit widths.

The terms “electronic communication.” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components.” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM. ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
store, at a first time, first data in a first section of an array of non-protected latches of the memory system;
store, in a first latch of the memory system, a first parity value associated with the first data stored in the first section of the array, the first latch associated with the first section of the array;
generate, at a second time, a second parity value associated with second data that is stored in the first section of the array of non-protected latches at the second time, wherein the second data is based at least in part on the first data and one or more environmental conditions to which the first section of the array is exposed between the first time and the second time;
generate a third parity value associated with the first section of the array based at least in part on the first parity value and the second parity value; and
output an error indication that indicates whether an error occurred within the array of non-protected latches between the first time and the second time based at least in part on the third parity value associated with the first section of the array.

2. The memory system of claim 1, wherein the processing circuitry is further configured to cause the memory system to:
generate a fourth parity value associated with a second section of the array; and
combine, in accordance with one or more logical operations, the third parity value and the fourth parity value, wherein the error indication is based at least in part on the combining.

3. The memory system of claim 2, wherein combining the third parity value and the fourth parity value in accordance with the one or more logical operations comprises the processing circuitry configured to cause the memory system to:
combine the third parity value and the fourth parity value in accordance with a logical OR operation, wherein the first section of the array comprises a first set of non-protected latches coupled in a serial configuration and the second section of the array comprises a second set of non-protected latches coupled in a serial configuration, and wherein the first latch associated with the first section of the array is coupled with a second latch associated with the second section of the array in a serial configuration.

4. The memory system of claim 1, wherein the processing circuitry is further configured to cause the memory system to:
compare the first parity value with the second parity value, wherein generating the third parity value is based at least in part on the comparing.

5. The memory system of claim 1, wherein the processing circuitry is further configured to cause the memory system to:
store, after generating the third parity value, the third parity value in the first latch;
generate a fourth parity value associated with third data that is stored in the first section of the array of non-protected latches at a third time, wherein the third data is based at least in part on the second data and the one or more environmental conditions to which the first section of the array is exposed between the second time and the third time;
compare the third parity value and the fourth parity value; and
generate a fifth parity value associated with the first section of the array based at least in part on the comparing.

6. The memory system of claim 5, wherein the first time, the second time, and the third time are based at least in part on a clock signal of the memory system.

7. The memory system of claim 1, wherein the processing circuitry is further configured to cause the memory system to:
output the third parity value, wherein the third parity value indicates whether a second error occurred within the first section of the array between the first time and the second time.

8. The memory system of claim 1, wherein outputting the error indication comprises the processing circuitry configured to cause the memory system to:
store the error indication to a register of the memory system, wherein the register is operable to be read by an external system.

9. The memory system of claim 1, wherein the processing circuitry is further configured to cause the memory system to:
output a plurality of error indications associated with a plurality of time periods of operation of the memory system, wherein each error indication indicates whether a respective error occurred within the array of non-protected latches during a respective time period, and wherein generation of each error indication of the plurality of error indications is based at least in part on a register command, a test mode, an error correction operation, one or more counters of the memory system, or any combination thereof.

10. The memory system of claim 1, wherein:
the error indication indicates whether the array of non-protected latches was exposed to radiation that may cause the error within the array of non-protected latches between the first time and the second time, and
the one or more environmental conditions comprise the radiation.

11. A memory system, comprising:
a plurality of option fuse latches;
a plurality of non-protected latches, one or more of which are coupled with one or more of the plurality of option fuse latches, wherein the plurality of non-protected latches are configured to support one or more test modes for the memory system, and wherein the plurality of non-protected latches comprises a plurality of lanes of non-protected latches;
a plurality of lane latches comprising a respective lane latch coupled with the plurality of lanes of non-protected latches, wherein the plurality of lane latches comprises a respective lane latch coupled with an output of each lane of the plurality of lanes of non-protected latches, and wherein the respective lane latch for a lane of non-protected latches is configured to generate parity information associated with the lane of non-protected latches; and
logic circuitry coupled with the plurality of lane latches and configured to generate an error indication based at least in part on a combination of the parity information generated by the plurality of lane latches.

12. The memory system of claim 11, wherein each respective lane latch of the plurality of lane latches of the memory system is associated with a corresponding lane of non-protected latches and is configured to generate respective parity information based at least in part on a comparison of a first set of parity bits associated with first data stored in the corresponding lane of non-protected latches at a first time and a second set of parity bits associated with second data stored in the corresponding lane of non-protected latches at a second time.

13. The memory system of claim 11, wherein the memory system comprises:
a mode register coupled with the logic circuitry, wherein the mode register is configured to store the error indication.

14. The memory system of claim 11, wherein the memory system comprises:
an array of protected latches coupled with the logic circuitry and configured to store data output by the plurality of non-protected latches.

15. The memory system of claim 11, wherein:
each lane of non-protected latches comprises a respective plurality of non-protected latches coupled in a serial configuration, and
an output of each non-protected latch of the respective plurality of non-protected latches in each lane is coupled with an input of a next non-protected latch of the respective plurality of non-protected latches in each lane in accordance with the serial configuration.

16. The memory system of claim 11, wherein:
the plurality of lane latches are coupled in a serial configuration, and
an output of a lane latch of the plurality of lane latches is coupled with an input of a next lane latch of the plurality of lane latches in accordance with the serial configuration.

17. The memory system of claim 11, wherein the memory system further comprises:
a plurality of second lane latches, wherein each second lane latch of the plurality of second lane latches is coupled with an output of a respective lane of the plurality of lanes of non-protected latches, and wherein each second lane latch is configured to latch data stored in the respective lane of non-protected latches.

18. The memory system of claim 17, wherein each second lane latch is in a parallel circuit configuration with a respective lane latch of the plurality of lane latches or is coupled with a selection component coupled with the respective lane latch.

19. The memory system of claim 11, wherein the memory system further comprises:
buffer circuitry and control circuitry coupled with an input of the plurality of lane latches.

20. A method by a memory system, comprising:
storing, at a first time, first data in a first section of an array of non-protected latches of the memory system;
storing, in a first latch of the memory system, a first parity value associated with the first data stored in the first section of the array, the first latch associated with the first section of the array;
generating, at a second time, a second parity value associated with second data that is stored in the first section of the array of non-protected latches at the second time, wherein the second data is based at least in part on the first data and one or more environmental conditions to which the first section of the array is exposed between the first time and the second time;
generating a third parity value associated with the first section of the array based at least in part on the first parity value and the second parity value; and
outputting an error indication that indicates whether an error occurred within the array of non-protected latches between the first time and the second time based at least in part on the third parity value associated with the first section of the array.
